(19) United States
(12) Patent Application Publication
(10) Pub. No.: US 2014/0209244 A1
(43) Pub. Date: Jul. 31, 2014

(54) SKEW ELIMINATION AND CONTROL IN A PLASMA ENHANCED SUBSTRATE PROCESSING CHAMBER

(71) Applicant: APPLIED MATERIALS, INC., Santa Clara, CA (US)

(72) Inventors: SAMER BANNA, San Jose, CA (US); WAHEB BISHARA, Menlo Park, CA (US); ALVARO GARCIA de GORORDO, San Francisco, CA (US); TZA-JING GUNG, San Jose, CA (US)

(21) Appl. No.: 13/833,428

(22) Filed: Mar. 15, 2013

Related U.S. Application Data
(60) Provisional application No. 61/756,822, filed on Jan. 25, 2013.

(51) Int. Cl. H01J 37/32

(52) U.S. Cl. CPC H01J 37/321
USPC 156/345.49

(57) ABSTRACT

Methods and apparatus for plasma-enhanced substrate processing are provided herein. In some embodiments, an apparatus for processing a substrate includes: a process chamber having an internal processing volume disposed beneath a dielectric lid of the process chamber; a substrate support disposed in the process chamber; one or more inductive coils disposed above the dielectric lid to inductively couple RF energy into the processing volume above the substrate support; and one or more first electromagnets to form a first static magnetic field that is substantially vertical in direction and axisymmetric about a central processing axis of the process chamber, and having a magnitude of about 2 to about 10 gauss within the processing volume proximate the lid.

### CROSS-REFERENCE TO RELATED APPLICATIONS

This application claims benefit of U.S. provisional patent application Ser. No. 61/756,822, filed Jan. 25, 2013, which is herein incorporated by reference.

### FIELD

Embodiments of the present invention generally relate to plasma enhanced semiconductor substrate processing.

### BACKGROUND

As uniformity requirements for better yield control are getting tighter and tighter, for example, as moving towards 20 nm node technology and beyond, any residual skew in a plasma reactor will limit reaching the tight specification for etch uniformity. The inventors believe that external magnetic field interference is among the few remaining skew sources that need to be addressed to achieve such a tight uniformity specification.

Thus, the inventors have provided embodiments of improved plasma-enhanced substrate process chambers.

### SUMMARY

Methods and apparatus for plasma-enhanced substrate processing are provided herein. In some embodiments, an apparatus for processing a substrate includes: a process chamber having an internal processing volume disposed beneath a dielectric lid of the process chamber; a substrate support disposed in the process chamber; one or more inductive coils disposed above the dielectric lid to inductively couple RF energy into the processing volume above the substrate support; and one or more first electromagnets to form a first static magnetic field that is substantially vertical in direction and axisymmetric about a central processing axis of the process chamber, and having a magnitude of about 2 to about 10 gauss within the processing volume proximate the lid.

In some embodiments, an apparatus for processing a substrate includes a process chamber having an internal processing volume disposed beneath a dielectric lid of the process chamber; a substrate support disposed in the process chamber; one or more inductive coils disposed above the dielectric lid to inductively couple RF energy into the processing volume above the substrate support; one or more first electromagnets to form a first static magnetic field having a magnitude of about 2 to about 10 gauss within the processing volume proximate the lid; and one or more second electromagnets to form a second static magnetic field having a magnitude of about 2 to about 10 gauss within the processing volume proximate and above the substrate support, wherein the one or more first electromagnets and the one or more second electromagnets are configured to form the first and second static magnetic fields substantially vertically in direction and axisymmetrically about a central processing axis of the process chamber.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of an inductively coupled plasma reactor in accordance with some embodiments of the present invention.

FIG. 2 depicts a schematic side view of an inductively coupled plasma reactor in accordance with some embodiments of the present invention.

FIGS. 3A-C depict schematic side views of electromagnet coil configurations in accordance with some embodiments of the present invention.

FIGS. 4A-D depict schematic side views illustrating magnetic field geometries in an inductively coupled plasma reactor in accordance with some embodiments of the present invention.

FIG. 5 depicts an exemplary configuration of a magnetic shield suitable for use in an inductively coupled plasma reactor in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention related to plasma-enhanced semiconductor process chambers. The inventors have observed that skew can be caused at least in part by external electromagnetic interference. In the past, when the uniformity specification was relatively high, the effect of external electromagnetic interference was not noticed. However, as process improvements have been made, and as the uniformity specification becomes increasingly tight, the inventors have now observed external electromagnetic interference as a source of skew. Skew generally refers to the difference in process results from one region of the substrate to another, such as left vs. right, center vs. edge, top vs. bottom of a feature, or the like (e.g., skew refers to the pattern of non-uniformity on the substrate). Skew can be used to characterize process results such as critical dimension (CD) uniformity, etch depth uniformity, or other process results.

As used herein, external electromagnetic interference refers to interference from electromagnetic fields not purposefully created within a process chamber, referred to herein as an external magnetic field. As used herein, the term external magnetic field does not refer to the location of the magnetic field, which can be internal to the process chamber. The term external magnetic field refers only to the source of the magnetic field, namely, from external electromagnetic interference. Sources of external electromagnetic interference include many sources surrounding the chamber, such as the Earth's magnetic field (typically on the order of about 0.3 gauss, although the exact value may vary even as between adjacent process chambers), magnetized parts of the mainframe such as structural steel, DC magnets in motors used for moving parts (cathode, lift pins, robots, etc.), interference from adjacent chambers, or the like. The inventors have discovered that a magnetic field of as low as 0.1 gauss can affect the overall skew in certain processes, once the overall skew magnitude is reduced significantly. Embodiments of the present invention may advantageously reduce, control, or eliminate skew induced by external magnetic field interference in industrial plasma etch reactors.

The inventors have investigated how a magnetic field near the lid/coils and within the volume of an inductively coupled plasma processing system affects the power distribution (e.g., center to edge) within the processing volume of the process chamber. When no magnetic field is provided, a first plasma distribution at or near lid is observed. Providing a magnetic field limits lateral movement of ionized particles in the chamber and a second, more uniform plasma distribution at or near the lid is observed. Providing a magnetic field strong enough to overcome the existing magnetic field created by external electromagnetic interference, for example about 5 gauss or so, adjacent to the lid has been observed to provide a more uniform plasma distribution within the chamber. The inventors have further observed that in some applications, providing this magnetic field may have a secondary effect—causing azimuthally-symmetric non uniform processing on the substrate, such as edge fast etching. However, the inventors have further discovered that providing another magnetic field at or above the substrate plane, in the opposite direction to the magnetic field near the lid, can compensate for that process non-uniformity. Thus, the natural skew can be overcome with the first magnetic field provided in the chamber near the chamber lid, with the center to edge uniformity enhanced by the second magnetic field provided in the chamber at or above the substrate plane. In applications where the center to edge uniformity is not an issue, the second magnetic field may be omitted.

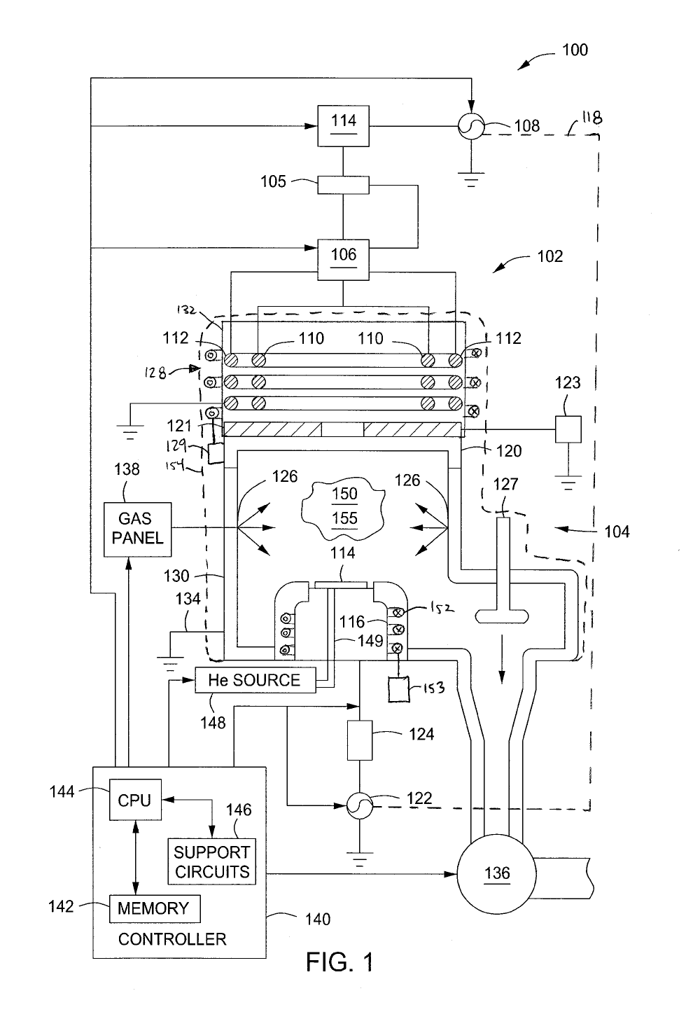

FIG. 1 depicts a schematic side view of an inductively coupled plasma reactor (reactor 100) in accordance with some embodiments of the present invention. FIG. 2 depicts a schematic side view of an inductively coupled plasma reactor 200 (reactor 200) in accordance with some embodiments of the present invention. The reactor 200 of FIG. 2 is a simplified version of the reactor 100 for a clearer understanding of embodiments of the present invention.

The reactor 100 may be utilized alone or, as a processing module of an integrated semiconductor substrate processing system, or cluster tool, such as a CENTURA® integrated semiconductor wafer processing system, available from Applied Materials, Inc. of Santa Clara, Calif. Examples of suitable plasma reactors that may advantageously benefit from modification in accordance with embodiments of the present invention include inductively coupled plasma etch reactors such as the DPS® line of semiconductor equipment or other inductively coupled plasma reactors, such as MESA™ or the like also available from Applied Materials, Inc. The above listing of semiconductor equipment is illustrative only, and other etch reactors, and non-etch equipment (such as CVD reactors, or other semiconductor processing equipment) may also be suitably modified in accordance with the present teachings. For example, suitable exemplary plasma reactors that may be utilized with the inventive methods disclosed herein are further described in U.S. patent application Ser. No. 12/821,609, filed Jun. 23, 2010 by V. Todorow, et al., and entitled, “INDUCTIVELY COUPLED PLASMA APPARATUS,” or U.S. patent application Ser. No. 12/821,636, filed Jun. 23, 2010 by S. Banna, et al., and entitled, “DUAL MODE INDUCTIVELY COUPLED PLASMA REACTOR WITH ADJUSTABLE PHASE COIL ASSEMBLY.”

The reactor 100 includes an inductive plasma source 102 disposed atop a process chamber 104. The inductive plasma source includes an RF feed structure 106 for coupling an RF power supply 108 to a plurality of RF coils, e.g., a first RF coil 110 and a second RF coil 112. The plurality of RF coils are coaxially disposed proximate the process chamber 104 (for example, above the process chamber) and are configured to inductively couple RF power into the process chamber 104 to form or control a plasma from process gases provided within the process chamber 104.

Illustrative plasma reactors may be configured for standard mode, where RF current flowing along the first RF coil 110 is in-phase with RF current flowing along the second RF coil 112, or dual mode, where the RF current flowing along the first RF coil 110 can be selectively in-phase or out-of-phase with RF current flowing along the second RF coil 112. For example, dual mode ICP sources have been introduced to eliminate M-shape and improve etch rate (ER) uniformity. For example, the reactor 100 as described herein is configured for dual mode operation.

The RF power supply 108 is coupled to the RF feed structure 106 via a match network 114. A power divider 105 may be provided to adjust the RF power respectively delivered to the first and second RF coils 110, 112. The power divider 105 may be coupled between the match network 114 and the RF feed structure 106. Alternatively, the power divider may be a part of the match network 114, in which case the match network will have two outputs coupled to the RF feed structure 106—one corresponding to each RF coil 110, 112. The power divider is discussed in more detail below.

The RF feed structure 106 couples the RF current from the power divider 105 (or the match network 114 where the power divider is incorporated therein) to the respective RF coils. For example, suitable exemplary RF feed structures that may be utilized with the inventive methods disclosed herein are described in U.S. patent application Ser. No. 12/821,626, filed Jun. 23, 2010 by Z. Chen, et al., and entitled, “RF FEED STRUCTURE FOR PLASMA PROCESSING.” In some embodiments, the RF feed structure 106 may be configured to provide the RF current to the RF coils in a symmetric manner, such that the RF current is coupled to each coil in a geometrically symmetric configuration with respect to a central axis of the RF coils, such as by a coaxial structure. Other configurations of RF feed structures may also be used.

The reactor 100 generally includes the process chamber 104 having a conductive or dielectric-coated body (wall) 130 and a dielectric lid 120 (that together define a processing volume), a substrate support pedestal 116 disposed within the processing volume, the inductive plasma source 102, and a controller 140. The wall 130 is typically coupled to an electrical ground 134. In some embodiments, the support pedestal 116 may provide a cathode coupled through a matching network 124 to a biasing power source 122. The biasing source 122 may illustratively be a source of up to about 1000 W (but not limited to about 1000 W) at a frequency of approximately 13.56 MHz that is capable of producing either continuous or pulsed power, although other frequencies and powers may be provided as desired for particular applications. In other embodiments, the source 122 may be a DC or pulsed DC source. In some embodiments, the source 122 may be capable of providing multiple frequencies or one or more second sources (not shown) may be coupled to the pedestal 116 through the same matching network 124 or one or more different matching networks (not shown) to provide multiple frequencies.

In some embodiments, a link 118 (shown in phantom) may be provided to couple the RF power supply 108 and the biasing source 122 to facilitate synchronizing the operation of one source to the other. Either RF source may be the lead, or master, RF generator, while the other generator follows, or is the slave. The link may further facilitate operating the RF power supply 108 and the biasing source 122 in perfect synchronization, or in a desired offset, or phase difference. The phase control may be provided by circuitry disposed within either or both of the RF source or within the link between the RF sources. This phase control between the source and bias RF generators (e.g., 108, 122) may be provided and controlled independent of the phase control over the RF current flowing in the plurality of RF coils coupled to the RF power supply 108. Further details regarding phase control between the source and bias RF generators may be found in U.S. Pat. No. 8,264,154, issued Sep. 11, 2012 to S. Banna, et al., and entitled, “Method and Apparatus for Pulsed Plasma Processing Using a Time Resolved Tuning Scheme for RF Power Delivery.”

In some embodiments, the dielectric lid 120 may be substantially flat. Other modifications of the chamber 104 may have other types of lids such as, for example, a dome-shaped lid or other shapes. The inductive plasma source 102 is typically disposed above the lid 120 and is configured to inductively couple RF power into the process chamber 104. The inductive plasma source 102 includes the first and second coils 110, 112, disposed above the dielectric lid 120. The relative position, ratio of diameters of each coil, and/or the number of turns in each coil can each be adjusted as desired to control, for example, the profile or density of the plasma being formed via controlling the inductance on each coil. Each of the first and second coils 110, 112 is coupled through the matching network 114 via the RF feed structure 106, to the RF power supply 108. The RF power supply 108 may illustratively be capable of producing up to about 4000 W (but not limited to about 4000 W) at a tunable frequency in a range from 50 kHz to 13.56 MHz, although other frequencies and powers may be provided as desired for particular applications.

The first and second RF coils 110, 112 can be configured such that the phase of the RF current flowing through the first RF coil can be in phase or out-of-phase with respect to the phase of the RF current flowing through the second RF coil. As used herein, the term “out-of-phase” can be understood to mean that the RF current flowing through the first RF coil is flowing in an opposite direction to the RF current flowing through the second RF coil, or that the phase of the RF current flowing through the first RF coil is shifted with respect to the RF current flowing through the second RF coil.

In some embodiments, the direction of the RF current flowing through each coil can be controlled by the direction in which the coils are wound. For example, in some embodiments, the first RF coil 110 may be wound in a first direction and the second RF coil 112 may be wound in a second direction which may be opposite the first direction. Accordingly, although the phase of the RF signal provided by the RF power supply 108 is unaltered, the opposing winding first and second directions of the first and second RF coils 110, 112 cause the RF current to be out of phase, e.g., to flow in opposite directions effectively producing a 180° phase shift.

In some embodiments, a power divider 105, such as a dividing capacitor, may be provided between the RF feed structure 106 and the RF power supply 108 to control the relative quantity of RF power provided to the respective first and second coils. For example, as shown in FIG. 1, a power divider 105 may be disposed in the line coupling the RF feed structure 106 to the RF power supply 108 for controlling the amount of RF power provided to each coil (thereby facilitating control of plasma characteristics in zones corresponding to the first and second coils). In some embodiments, the power divider 105 may be incorporated into the match network 114. In some embodiments, after the power divider 105, RF current flows to the RF feed structure 106 where it is distributed to the first and second RF coils 110, 112. Alternatively, the split RF current may be fed directly to each of the respective first and second RF coils.

Optionally, one or more electrodes (not shown) may be electrically coupled to one of the first or second coils 110, 112, such as the first coil 110. The one or more electrodes may be two electrodes disposed between the first coil 110 and the second coil 112 and proximate the dielectric lid 120. Each electrode may be electrically coupled to either the first coil 110 or the second coil 112, and RF power may be provided to the one or more electrodes via the RF power supply 108 via the inductive coil to which they are coupled (e.g., the first coil 110 or the second coil 112). In some embodiments, the one or more electrodes may be movably coupled to one of the one or more inductive coils to facilitate the relative positioning of the one or more electrodes with respect to the dielectric lid 120 and/or with respect to each other. A more detailed description of the electrodes and their utilization in plasma processing apparatus can be found in U.S. Pat. No. 8,299,391, issued Oct. 30, 2012 to V. Todorow, et al., and titled “Field Enhanced Inductively Coupled Plasma (FE-ICP) Reactor.”

A heater element 121 may be disposed atop the dielectric lid 120 to facilitate heating the interior of the process chamber 104. The heater element 121 may be disposed between the dielectric lid 120 and the first and second coils 110, 112. In some embodiments. the heater element 121 may include a resistive heating element and may be coupled to a power supply 123, such as an AC power supply, configured to provide sufficient energy to control the temperature of the heater element 121 to be between about 50 to about 100 degrees Celsius. In some embodiments, the heater element 121 may be an open break heater. In some embodiments, the heater element 121 may comprise a no break heater, such as an annular element, thereby facilitating uniform plasma formation within the process chamber 104.

One or more first electromagnets 128 may be provided to form a first magnetic field within the inner volume of the process chamber at or near the lid 120. In some embodiments, the first magnetic field has a substantially vertical direction and is axisymmetric about a central processing axis of the process chamber. The central processing axis may also be aligned with a center of the substrate, when disposed on the substrate support, and with the electric field induced by the inductive plasma source 102 during operation.

The first magnetic field has a magnitude that is greater than that of an external magnetic field created by the external electromagnetic interference. The first magnetic field is configured to overwhelm the external magnetic field at least along a z axis (e.g., a vertical axis in embodiments where the substrate is disposed processing side up on a substrate support with the inductive plasma source disposed overhead). The inventors have observed that the magnitude of the external magnetic field is typically less than 1 gauss, such as about 0.2 to about 0.5 gauss and may vary over time and location (for example, as between adjacent chambers). In some embodiments, the first magnetic field may have a magnitude of about one order of magnitude greater (e.g., about 10 times greater) than the magnitude of the external magnetic field. In some embodiments, the first magnetic field may have a strength of a few gauss, for example about 2 to about 10 gauss.

In some embodiments, the one or more first electromagnets 128 may comprise one or more wires wound repeatedly about the chamber that can be coupled to a power source, such as a DC power supply. The wire gauge, number of turns or coils, and current provided may be controlled to provide a magnetic field of the desired magnitude. In some embodiments, the one or more first electromagnets 128 may comprise a plurality of electromagnets arranged about the chamber that together provide the desired first magnetic field.

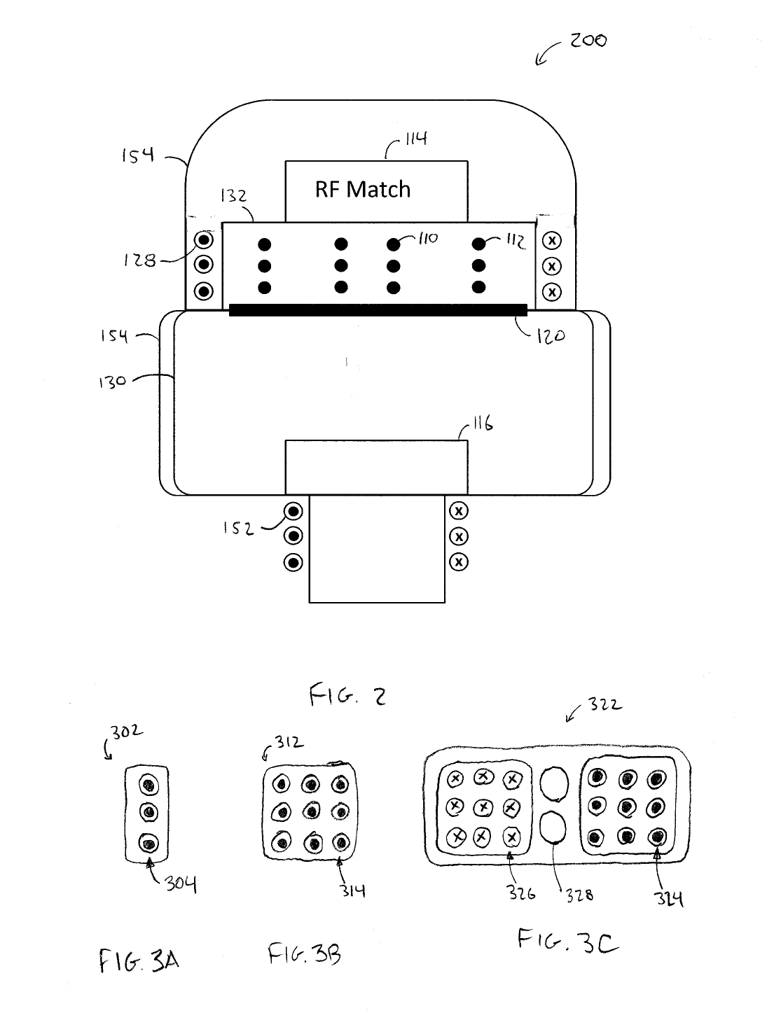

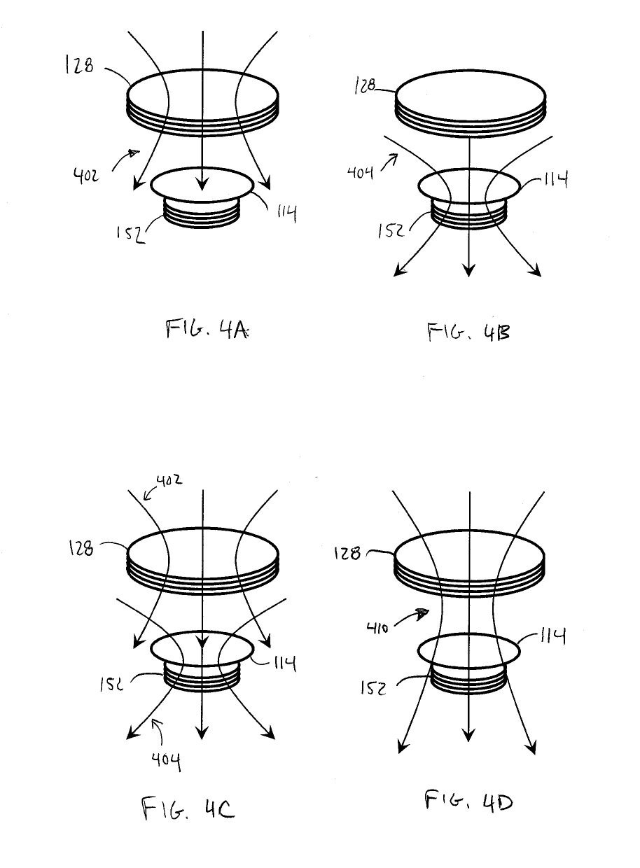

For example, as depicted in cross section in FIG. 3A, an electromagnet 302 may comprise a coil 304 of one or more wires wrapped in one layer in the same direction (e.g., having the same polarity). Alternatively, as depicted in cross section in FIG. 3B, an electromagnet 312 may comprise a coil 314 of one or more wires wrapped in a plurality of layers, three layers shown for illustration (e.g., having the same polarity). Alternatively, as depicted in cross section in FIG. 3C, an electromagnet 322 may comprise a first coil 324 and a second coil 326 spaced apart from and disposed radially outward of the first coil 324. The spacing between the first and second coils 324, 326 may be selected based upon the magnitude of the electromagnetic field (e.g., the wire gauge, number of turns, current, and the like). In some embodiments, the first and second coils 324, 326 may be spaced apart by about 1 mm to about 10 cm, or about 3 cm. The first and second coils 326 may be concentric and substantially co-planar. The first coil 324 comprises one or more wires wrapped in a plurality of layers, three layers shown for illustration, and having a first polarity. The second coil 326 comprises one or more wires wrapped in a plurality of layers, three layers shown for illustration, and having a second polarity. In some embodiments, the first polarity and the second polarity are the same. In some embodiments, the first polarity and the second polarity are opposite (as depicted in FIG. 3C).

If desired, the electromagnet 322 (or any of the other electromagnets disclosed herein) may be cooled, for example by flowing a suitable coolant through conduits in the electromagnet, such as conduits 328 shown in FIG. 3C.

In embodiments where two adjacent coils are provided having opposite polarity, such as depicted in FIG. 3C, the first magnetic field may advantageously be localized within the process chamber 104, thus minimizing the impact on any adjacent process chambers. The spacing between the adjacent coils with opposite polarity and the ratio of magnetic fields generated by the two coils allow additional control over the distribution and localization of the first magnetic field in an axisymmetric fashion.

Returning to FIG. 1, in some embodiments, the one or more first electromagnets 128 may be disposed about a housing 132 that surrounds the first and second coils, 110, 112. The housing 132 may be cylindrical and centered about a central processing axis that passes through the center of the substrate, when disposed on the substrate support 116. As such, in some embodiments, the one or more electromagnets may advantageously be disposed about the housing 132, resulting in a first magnetic field that is symmetric about the central processing axis, and therefore, with the electric field induced by the first and second coils 110, 112 during operation.

In some embodiments, one or more second electromagnets 152 may be provided below the substrate plane to provide a second magnetic field at or just above the substrate plane. The one or more second electromagnets 152 may be as described in any of the embodiments disclosed herein for the one or more first electromagnets 128. The second magnetic field may have a strength of a few gauss, e.g., in the same range as discussed above with respect to the first magnetic field. The first and the second magnetic field may have the same magnitude or different magnitudes. The one or more second electromagnets 152 may have the same polarity or the opposite polarity as the one or more first electromagnets 128. The one or more second electromagnets 152 may be configured to provide the second magnetic field to compensate for any center to edge non-uniformities when processing the substrate. For example, the one or more second electromagnets 152 may be configured to provide the second magnetic field to compensate for any divergence of the magnetic field lines of the first magnetic field from the z-axis, or vertical. The second magnetic field may be additive to or may subtract from the magnitude of the first magnetic field near the substrate to provide more uniform processing results. The relative strength of the first and second magnetic fields can be controlled to provide extreme edge control of substrate process results (e.g., process results within about 3 millimeters from the edge of the substrate). For example, increasing the magnitude of the combined magnetic field in a direction toward the substrate can increase the etch rate at the edge of the substrate (edge etch rate) as compared to an etch rate of a center region of the substrate (center etch rate). Conversely, decreasing the magnitude of the combined magnetic field in a direction toward the substrate can decrease the edge etch rate as compared to the center etch rate.

In some embodiments either or both of the first electromagnets 128 and second electromagnets 152 may be DC electromagnets comprising wires wrapped around the housing 132 and/or substrate support 116 and powered by respective adjustable DC power supplies. The number of turns can vary depending on the wire gauge from few turns to hundreds of turns, such as about 10 turns to about 500 turns. The currents can vary from few tens of mAmps to few to tens of Amps, such as about 50 mAmps to about 20 Amps.

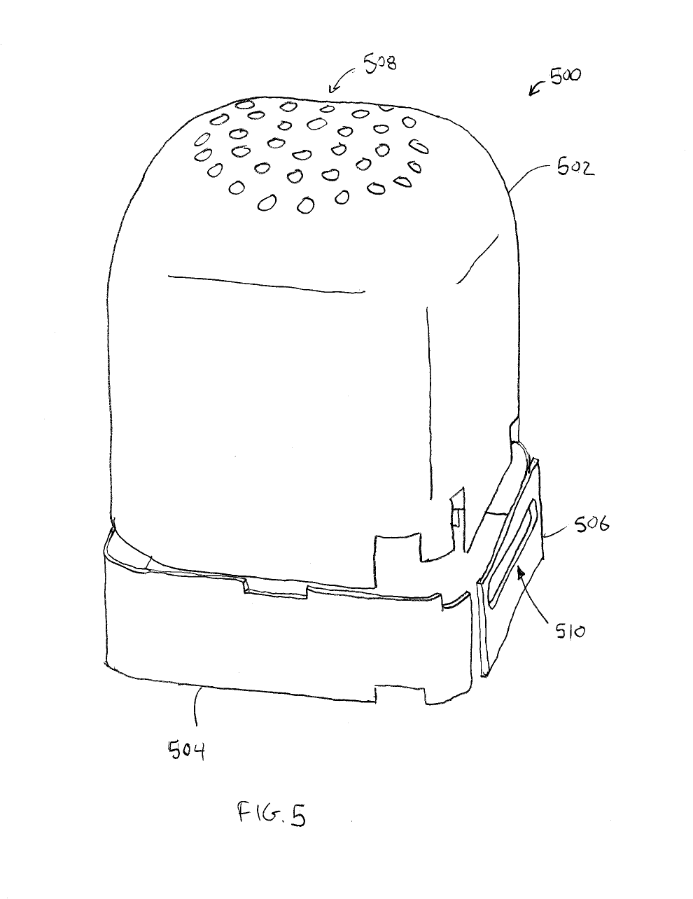

By way of illustration, FIGS. 4A-D respectively depicts schematic views of the magnetic fields created by the one or more first electromagnets 128 and the one or more second electromagnets 152 and their cumulative effect on a substrate 114. FIG. 4A depicts a schematic view of the one or more first electromagnets 128 disposed above the substrate 114 and the one or more second electromagnets 152 disposed below the substrate 114. In FIG. 4A, only a first magnetic field 402 is shown, created by the one or more first electromagnets 128. In FIG. 4B, only a second magnetic field 404 is shown, created by the one or more second electromagnets 152. In FIG. 4C, the first and second magnetic fields 402, 404 are shown overlapped (e.g., present at the same time). FIG. 4D depicts a cumulative, or composite magnetic field 410 formed by the combined effect of the first and second magnetic fields 402, 404.

Returning to FIG. 1, in some embodiments, the position of either or both of the one or more first electromagnets 128 and the one or more second electromagnets 152 may be controlled to more precisely control the position or geometry of the first magnetic field (e.g., 402), the second magnetic field (e.g., 404), or the composite magnetic field (e.g., 410). For example, in some embodiments, an actuator 129 may be coupled to the one or more first electromagnets 128 to control an axial position of the one or more first electromagnets 128. The one or more first electromagnets 128 may be moved, for example, in a range of from a position partially below the lid 120, to a position partially above the first and second coils 110, 112. In some embodiments, the one or more first electromagnets 128 may be moved in a range of about 1 to about 6 inches.

Alternatively or in combination, in some embodiments, an actuator 153 may be coupled to the one or more second electromagnets 152 to control an axial position of the one or more second electromagnets 152. The one or more second electromagnets 152 may be moved, for example, in a range of from a position partially above the substrate 114, to a position completely below the substrate 114. In some embodiments, the one or more second electromagnets 152 may be moved in a range of about 1 to about 6 inches. Although depicted as disposed about the substrate support 116, the one or more second electromagnets 152 may alternately or in combination be disposed about the chamber wall 130 at the same axial position as described above.

Alternatively or in combination, in some embodiments, a magnetic shield 154 may be provided about the process chamber 104 (and the one or more first electromagnets 128 and/or the one or more second electromagnets 152) to shield the process chamber 104 or portions thereof from the external magnetic field. The magnetic shield 154 may be fabricated from mu-metals or other suitable materials having a high magnetic permeability (e.g., a relative permeability, μ/μ₀, of about 5,000 to about 500,000). The magnetic shield 154 may be formed of a single layer or of multiple alternating layers of a high magnetic permeability material and a non-magnetic material (such as PTFE, PEEK, aluminum, or the like). Multiple layers may be about 0.1 to about 2 inches in thickness. Different layers of the high magnetic permeability material and/or different layers of the non-magnetic material may be the same or different. The choice of the material will depend upon the magnitude of the magnetic field to be shielded, the temperature at which the shielding is desired to occur, the thickness of the material, the number of layers of the material, and the desired attenuation (e.g., 100 times reduction, 1,000 times, 5,000 times, etc.).

In some embodiments, the magnetic shield 154 may be provided about the entire process chamber 104 or about substantially the entire process chamber 104 (for example, excluding a floor of the process chamber). However, due to mechanical limitations and practicality considerations, it may be difficult or impractical to shield the entire process chamber. In some embodiments, the magnetic shield 154 may be provided about the plasma creation area of the process chamber 104. For example, the magnetic shield 154 may be provided about the inductive plasma source 102 and/or a region of the process chamber 104 suitable to shield the area adjacent to and below the lid 120. The external magnetic field alters the power coupling of the RF energy provided by the inductive plasma source 102 to the region beneath the lid 120, thereby undesirably impacting plasma formation and distribution. By shielding the plasma creation area, the impact of the external magnetic field on the power coupling may advantageously be minimized or eliminated. Moreover, in embodiments where both a magnetic shield 154 and the one or more first electromagnets 128 and the one or more second electromagnets 152 are provided within the shield, the magnetic shield 154 provides both shielding of the external magnetic field from impacting the process chamber 104 as well as shielding any adjacent chambers from the electromagnetic field created by the one or more first electromagnets 128 and the one or more second electromagnets 152.

FIG. 5 depicts an exemplary configuration of a magnetic shield 500 suitable for use as the magnetic shield 154. The magnetic shield 500 includes a plasma source shield 502 sized to fit over the inductive plasma source 102. The plasma source shield 502 may be cylinder or half-sphere. A plurality of holes 508 may be disposed in an upper region of the plasma source shield 502 to allow heat from within the shielded volume to dissipate. In some embodiments, the magnetic shield 500 may further include a chamber body shield 504 sized to surround the sides of the chamber body 104. A mounting plate 506 may be provided to couple the chamber body shield 504 to the chamber body 104. Openings may be provided as necessary to provide access to the process chamber 104, such as a slit valve opening 510 to allow access to a slit valve of the chamber body 104.

During operation, a substrate 114 (such as a semiconductor wafer or other substrate suitable for plasma processing) may be placed on the pedestal 116 and process gases may be supplied from a gas panel 138 through entry ports 126 to form a gaseous mixture 150 within the process chamber 104. The gaseous mixture 150 may be ignited into a plasma 155 in the process chamber 104 by applying power from the plasma source 108 to the first and second coils 110, 112 and optionally, the one or more electrodes (not shown). The one or more first electromagnets 128 provides the first magnetic field that overcomes the natural magnetic field within the chamber, thereby providing a more uniform plasma distribution within the process chamber 104. The one or more second electromagnets 152 may provide the second magnetic field to enhance uniformity of the plasma proximate the substrate. In embodiments where the magnetic shield 154 is provided, the external magnetic field may be further shielded, thereby further minimizing any effect on the process due to the external magnetic field. In some embodiments, power from the bias source 122 may be also provided to the pedestal 116. The pressure within the interior of the process chamber 104 may be controlled using a throttle valve 127 and a vacuum pump 136. The temperature of the chamber wall 130 may be controlled using liquid-containing conduits (not shown) that run through the wall 130.

The temperature of the wafer 114 may be controlled by stabilizing a temperature of the support pedestal 116. In one embodiment, helium gas from a gas source 148 may be provided via a gas conduit 149 to channels defined between the backside of the wafer 114 and grooves (not shown) disposed in the pedestal surface. The helium gas is used to facilitate heat transfer between the pedestal 116 and the wafer 114. During processing, the pedestal 116 may be heated by a resistive heater (not shown) within the pedestal to a steady state temperature and the helium gas may facilitate uniform heating of the wafer 114. Using such thermal control, the wafer 114 may illustratively be maintained at a temperature of between 0 and 500 degrees Celsius.

The controller 140 comprises a central processing unit (CPU) 144, a memory 142, and support circuits 146 for the CPU 144 and facilitates control of the components of the reactor 100 and, as such, of methods of forming a plasma, such as discussed herein. The controller 140 may be one of any form of general-purpose computer processor that can be used in an industrial setting for controlling various chambers and sub-processors. The memory, or computer-readable medium, 142 of the CPU 144 may be one or more of readily available memory such as random access memory (RAM), read only memory (ROM), floppy disk, hard disk, or any other form of digital storage, local or remote. The support circuits 446 are coupled to the CPU 144 for supporting the processor in a conventional manner. These circuits include cache, power supplies, clock circuits, input/output circuitry and subsystems, and the like. The memory 142 stores software (source or object code) that may be executed or invoked to control the operation of the reactor 100 in the manner described below. Specifically, memory 142 stores a calibration module 190 that is executed to calibrate the ratio of current or power applied to the coils 110 and 112. The software routine may also be stored and/or executed by a second CPU (not shown) that is remotely located from the hardware being controlled by the CPU 144.

While the foregoing is directed to embodiments of the present invention, other and further embodiments of the invention may be devised without departing from the basic scope thereof.

1. An apparatus for processing a substrate, comprising:
a process chamber having an internal processing volume disposed beneath a dielectric lid of the process chamber;
a substrate support disposed in the process chamber;
one or more inductive coils disposed above the dielectric lid to inductively couple RF energy into the processing volume above the substrate support; and
one or more first electromagnets to form a first static magnetic field that is substantially vertical in direction and axisymmetric about a central processing axis of the process chamber, and having a magnitude of about 2 to about 10 gauss within the processing volume proximate the lid.

2. The apparatus of claim 1, further comprising:
one or more second electromagnets to form a second static magnetic field having a magnitude of about 2 to about 10 gauss within the processing volume proximate and above the substrate support.

3. The apparatus of claim 2, wherein the one or more second electromagnets are configured to form the second static magnetic field substantially vertically in direction and axisymmetrically about a central processing axis of the process chamber.

4. The apparatus of claim 2, further comprising an actuator configured to move the one or more second electromagnets from a first position partially above a support surface of the substrate support to a second position substantially completely below the support surface.

5. The apparatus of claim 1, further comprising an actuator configured to move the one or more first electromagnets between a first position partially below the dielectric lid to a second position partially above the one or more inductive coils.

6. The apparatus of claim 1, wherein the one or more first electromagnets further comprise a coil of one or more wires wrapped in a plurality of layers having the same polarity.

7. The apparatus of claim 1, wherein the one or more first electromagnets further comprise:
a first coil of one or more wires wrapped in a first plurality of layers and having a first polarity; and
a second coil of one or more wires wrapped in a second plurality of layers having a second polarity, wherein the second coil is disposed radially outward of the first coil at a first distance.

8. The apparatus of claim 7, wherein the first polarity and the second polarity are the same.

9. The apparatus of claim 7, wherein the first polarity is opposite of the second polarity.

10. The apparatus of claim 7, wherein the first distance is about 1 mm to about 10 cm.

11. The apparatus of claim 1, further comprising:
a magnetic shield disposed about the one or more inductive coils and a plasma forming region of the internal processing volume.

12. The apparatus of claim 11, wherein the magnetic shield is disposed about substantially the entire process chamber.

13. The apparatus of claim 11, wherein the magnetic shield comprises a plasma source shield and a chamber body shield.

14. The apparatus of claim 11, wherein the magnetic shield is only disposed about the one or more inductive coils and the plasma forming region of the internal processing volume.

15. The apparatus of claim 11, wherein the magnetic shield is comprised of a material having a relative permeability of about 5,000 to about 500,000.

16. The apparatus of claim 15, wherein the magnetic shield is comprised of multiple alternating layers of a high magnetic permeability material and a non-magnetic material.

17. An apparatus for processing a substrate, comprising:
a process chamber having an internal processing volume disposed beneath a dielectric lid of the process chamber;
a substrate support disposed in the process chamber;
one or more inductive coils disposed above the dielectric lid to inductively couple RF energy into the processing volume above the substrate support;
one or more first electromagnets to form a first static magnetic field having a magnitude of about 2 to about 10 gauss within the processing volume proximate the lid; and
one or more second electromagnets to form a second static magnetic field having a magnitude of about 2 to about 10 gauss within the processing volume proximate and above the substrate support, wherein the one or more first electromagnets and the one or more second electromagnets are configured to form the first and second static magnetic fields substantially vertically in direction and axisymmetrically about a central processing axis of the process chamber.

18. The apparatus of claim 17, further comprising:
a magnetic shield disposed about the one or more inductive coils and a plasma forming region of the internal processing volume.

19. The apparatus of claim 18, wherein the magnetic shield is disposed about substantially the entire process chamber.

20. The apparatus of claim 17, further comprising an actuator configured to vertically move either or both of the one or more first electromagnets or the one or more second electromagnets.
